(19) United States
(12) Patent Application Publication
(10) Pub. No.: US 2009/0257601 A1
(43) Pub. Date: Oct. 15, 2009

(54) ACOUSTIC SPEAKER SYSTEM WITH STRONG BASS CAPABILITY

(76) Inventor: Marvin Andrew Motsenbocker, Fredericksburg, VA (US)

Correspondence Address: MARVIN MOTSENBOCKER, 17 WALLACE FARMS LANE, FREDERICKSBURG, VA, 22406, US

(21) Appl. No.: 12/421,553

(22) Filed: Apr. 9, 2009

Related U.S. Application Data
(60) Provisional application No. 61/044,480, filed on Apr. 12, 2008.

(51) Int. Cl. G10K 11/16; H03F 99/00

(52) U.S. Cl. 381/71.11; 381/120

(57) ABSTRACT

Sound reproduction systems are described that have superior response to pure bass frequency signals from musical instruments such as electric bass guitar and string bass. A first amplifier drives a low frequency woofer and a second amplifier drives a full range speaker system. The bass component of the audio signal handled by the second amplifier is monitored and progressively compressed as the bass energy approaches a critical level that may damage one or more elements of the full range speaker. Speaker protection devices are also described that passively limit damaging pulses into speakers typically caused by plugging in equipment.

### REFERENCES TO PRIORITY FILINGS

This application receives priority from U.S. No. 61/044,480 filed Apr. 12, 2008 by inventor Marvin Motsenbocker and from U.S. Ser. No. 12/136,012 filed Jun. 9, 2008 by inventor Marvin Motsenbocker, both of which are incorporated by reference in their entireties.

### FIELD OF THE INVENTION

The invention relates to audio reproduction systems and particularly to high fidelity systems that accommodate high level bass sounds.

### BACKGROUND OF THE INVENTION

Loudspeaker systems usually contain different kinds of speakers (woofer, mid-range, tweeter, for example) to handle different pitches of sound. Typically, a passive crossover connects an amplifier output, and sends different frequencies to different speakers.

Some guitar speakers use only a single speaker element and are not high fidelity. Furthermore, a bass guitar generally cannot drive a high fidelity system at high power levels without destroying speaker(s). Therefore, most bass guitar amplifier designs are limited to big woofer speaker elements and often sound muddy. Even regular guitar amps, which may use two or more speaker elements, sound horrible and are better suited to generate noise and distortion, which can be very useful in hiding lack of player talent.

Many guitar and bass players want high volume and clean sound over a wide range of audio, in particular at least from 40 hertz to 10,000 hertz, and preferably from 35 hertz to 15,000 hertz. This need is particularly acute for acoustic bass instruments, which need high power low note reproduction but also mids and highs, for clarity.

### SUMMARY OF THE INVENTION

An embodiment provides a multiple speaker system capable of handling low bass guitar input comprising a first amplifier; a second amplifier configured to reproduce a full range of frequencies; a woofer connected to the first amplifier; a full range speaker for reproducing a full range of audio sound coupled to the second amplifier; a first circuit that preferentially causes bass frequencies to enter the woofer; and a second circuit that progressively hinders bass frequencies from entering the full range speaker at high energy levels.

Another embodiment provides a device located between an amplifier and a speaker that protects the speaker, comprising a detector of audio pulse and a circuit that responds by quenching (shorting to ground) power to the speaker, as described herein.

Another embodiment provides an active-passive woofer system for reproduction of a musical instrument comprising: a cabinet with an airspace;

a first subwoofer amplifier and a second amplifier controlled by a bass compressor, wherein both amplifiers receive an audio signal simultaneously;

a first woofer or subwoofer mounted in the cabinet and contacting the airspace, and electrically connected to receive amplified energy from the first subwoofer amplifier; a second woofer mounted in the cabinet and contacting the airspace, and electrically connected to receive amplified energy from the second amplifier; wherein

the second woofer actively reproduces bass notes from energy received from the second amplifier at lower volume levels and progressively acts as a passive radiator of the first woofer or subwoofer at higher audio signal levels.

Many other embodiments will be appreciated by a skilled artisan.

### DESCRIPTION OF THE DRAWINGS

FIG. 1 is a block diagram of a representative embodiment of audio signal manipulation and audio output.

FIG. 2 is a block diagram of another representative embodiment.

FIG. 3 is a graph that shows overall working of some representative embodiments.

FIG. 4 is a representative circuit diagram of an embodiment.

FIG. 5 is a multi-use adapter apparatus embodiment of the invention.

FIG. 6 shows three representative applications of the multi-use adapter apparatus.

FIG. 7 is a passive (external powered) control system.

FIG. 8 shows circuit details for a representative embodiment of the passive apparatus.

FIG. 9 shows circuit details for another embodiment of the passive apparatus.

### DETAILED DESCRIPTION

Combine Amplifiers/Bass Compressor/Speakers

Talented musicians need a high fidelity system that can reproduce not only regular music signals but also bass instrument signals, while limiting damage to the speakers. To address this need, a circuit combination using multiple amplifiers (at least two) that separately drive a woofer and a high fidelity speaker or speaker combination with a bass compressor was made and gave surprisingly good acoustic results. In particular, good bass response and high volume, particularly with a bass instrument such as a bass guitar, acoustic bass, or electric upright bass was achieved without sacrificing fidelity.

The terms “full range speaker,” “high fidelity speaker,” and “speaker” are used interchangeably and can mean one or multiple speakers. The terms “woofer” and “subwoofer” are known in the art and usually mean one speaker that is normally commercially sold as such, as well as combinations of two or more.

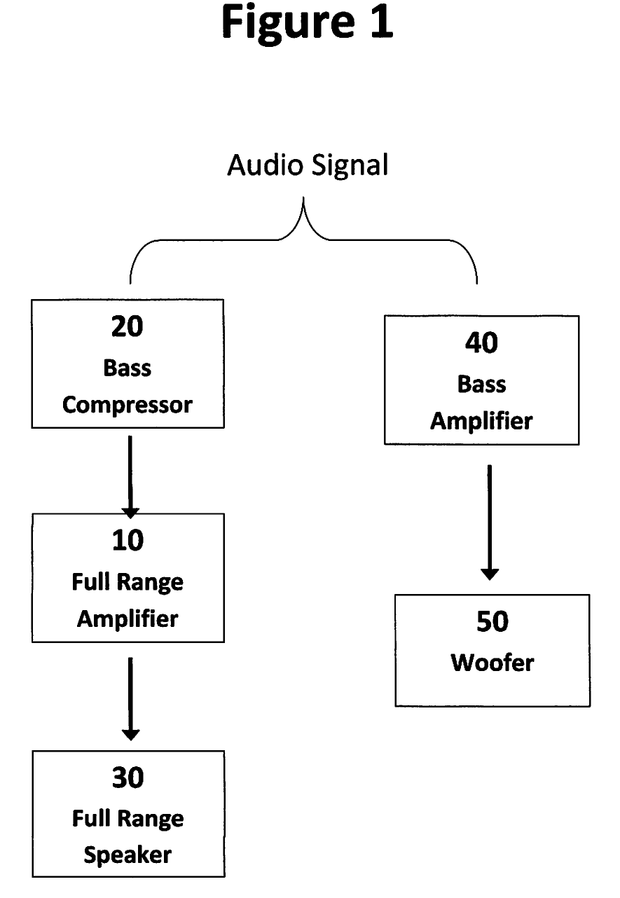

In an embodiment, a signal such as a full range music signal is processed by at least two amplifiers and passed to at least two sets of speaker(s) as exemplified in FIG. 1. In this example, a first audio amplifier 10 is combined with a bass compressor 20 that compresses bass frequencies (generally less than 250 hertz, particularly less than 100 hertz, more particularly less than 50 hertz, most preferably including the low E on a bass guitar at 41 hertz). The output from first amplifier 10 drives a full range speaker system 30 (i.e. one or more speakers that normally handle a full audio range, preferably a coaxial speaker that combines two or more speaker driver elements.) A second audio amplifier 40 amplifies bass (preferably has a bass low pass filter) and drives a bass speaker element 50 such as a woofer or subwoofer preferably at low frequencies only. The speakers preferably share the same cabinet space but may be separate.

A preferred combination is: a) a bass power controller of a full range speaker system; with b) a subwoofer. The power controller preferably is not a limiter that chops signal off above a given power level but is a compressor that gradually limits bass power to speakers as bass power is increased. A preferred power controller is a bass compressor located before an amplifier to a full range speaker or speaker system, although other control systems that achieve this result are contemplated as well.

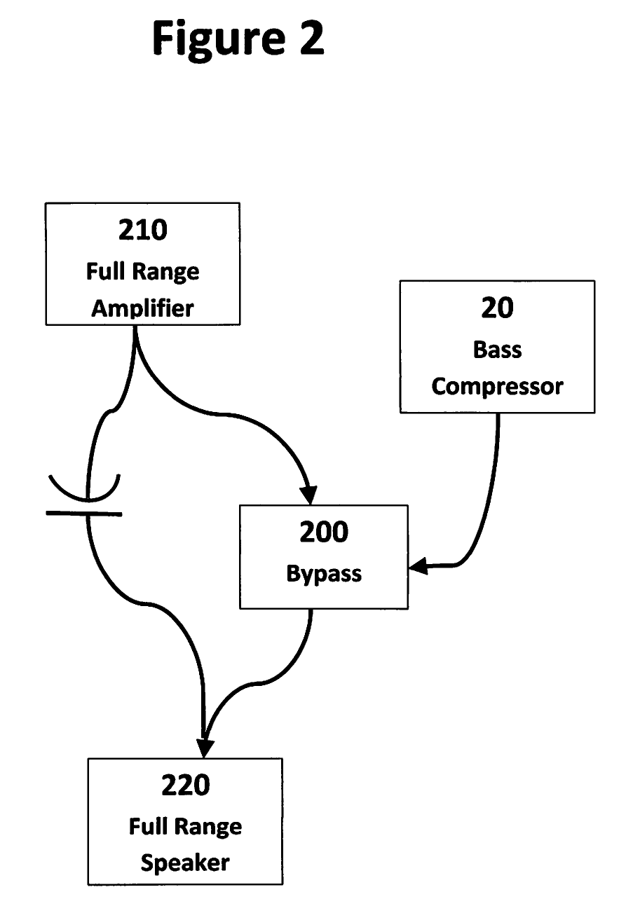

For example, FIG. 2 exemplifies a speaker bypass wherein switch 200 is normally closed and conducts low and high frequency full range power levels from amplifier 210 to full range speaker 220. 200 may be a MOSFET that progressively increases resistance as controlled by bass compressor 20 in response to increasing bass strength (most preferably total power in a bass region, less desirably could be relative proportion of bass in the total signal). As the bass frequency power level of the signal being amplified increases, 200 opens in response to a signal from 20, and presents a progressively higher resistance to the bass frequency component of the signal. High pass filter 230, which preferably comprises a capacitor in parallel with 200 allows higher frequency power to pass so that bass frequencies are progressively impeded at the higher bass frequency levels.

In a more preferable embodiment (FIG. 1) the bass audio region of an audio signal is compressed by compressor 20 and then amplified by full range amplifier 10. Full range speaker 30 may be separate components (preferably two or more of: woofer, midwoofer, midrange, tweeter, super tweeter etc.) or more desirably is a coaxial speaker that contains multiple speaker elements.

### Provision of Bass Power to the Bass Woofer/Subwoofer

Bass power may be supplied unhindered or boosted to the bass woofer speaker. Because woofers usually are more responsive to the bass energy portion of an audio signal, a complete audio signal may be used to drive the woofer. Preferably, however, enhanced bass is used and prepared for example by a low pass filter or bass boost. In a preferred embodiment more than 90%, preferably more than 95% and yet more preferably more than 99% of the RMS power to the bass woofer is less than 250 hertz, preferably less than 200 hertz yet more preferably less than 150 hertz and even yet more preferably less than 100 hertz.

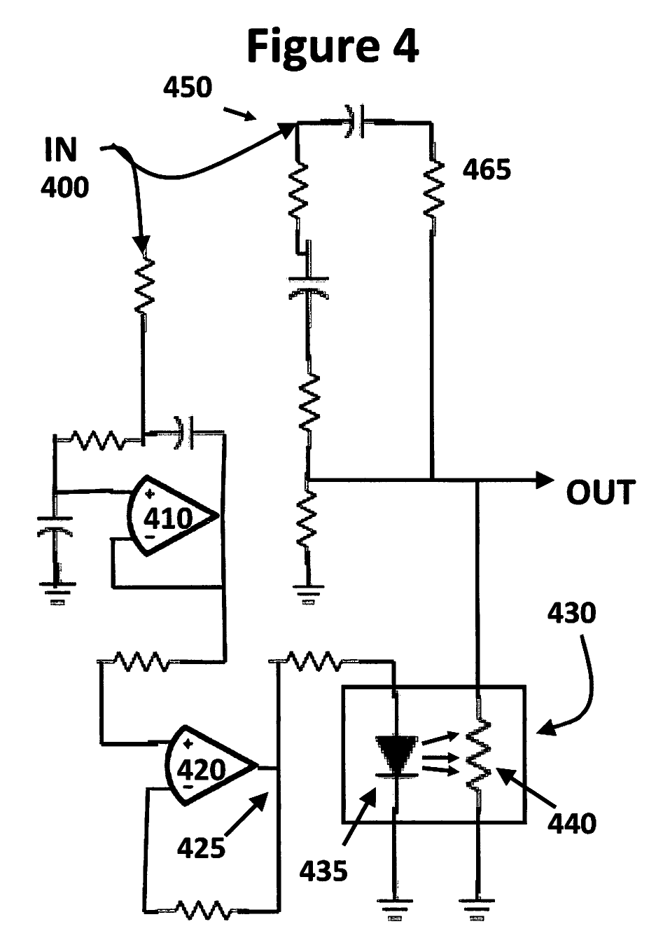

In a preferred embodiment the energy fed to the bass woofer/subwoofer is at an RMS level that is at least 50% greater than the power supplied to the full range speaker and more preferably at least twice the RMS power supplied to the full range speaker. In an experiment a 70 watt subwoofer amplifier was used to drive an eight inch subwoofer speaker element and a 20 watt full range amplifier was used to drive a 6 by 9 inch full range 3 way coaxial car speaker, with excellent results. The 20 watt full range amplifier was fed by a preamplifier that had an optical bass compressor as described in FIG. 4.

### Limitation of Bass Power to the Full Range Speaker

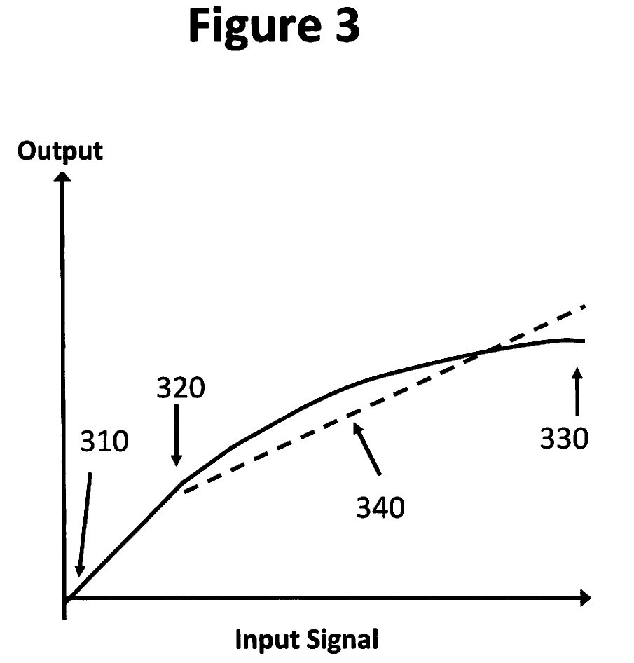

Preferably the limitation of the bass portion of the audio signal fed to the full range speaker compressor does not occur at lower power levels, but starts at higher levels with a soft knee as shown in FIG. 3. This figure shows a progressive control of bass power to the full range speaker from a control signal. The X axis is audio bass signal power and the Y axis is compressed output. At position 310 to 320 the signal is not compressed. From 320 to 330 a gradual restriction occurs, which mostly or completely levels off at 330. In another embodiment shown as dotted line 340 in FIG. 3, the power does not level off but slowly increases continuously. In practice, position 330 should be set to just below the level at which the speaker system suffers damage.

Parameters should be adjusted to compress the bass at higher levels so that the total amount of bass stays below the level that creates speaker damage. Parameter selection can be carried out for example by applying a sine wave at the lowest desired frequency (eg. 40 Hz for a 4 string bass guitar) and increasing power to the speaker until clipping or other audible distortion becomes evident, and then backing off until the distortion goes away. In a desirable embodiment, the maximum power is cut back at least 5% or at least 10% from this level for a safety margin.

Preferably, a bass compressor is used before an amplifier to the full range speaker. Preferably, the compression has a fast attack between 0.5 milliseconds and 100 ms, and more preferably between 1 millisecond and 25 milliseconds. The compression preferably has a slow decay of between 5 ms to 10 seconds, more preferably between 10 milliseconds and 1 second and yet more preferably between 20 milliseconds and 500 milliseconds. The definitions of attack and decay are those customarily used most often by skilled artisans. If this is unclear to a reader, the reader should follow the teachings presented in the Silonex catalog (Montreal, Canada) of optical compressor devices, for guidance.

### Representative Compression Techniques

Desirable bass compressors often measure RMS signal in a sample chain and then control gain of an op amp. Think Corp. has some great devices that may be used, although optical compressors sold by Silonex were preferred due to their simplicity.

It was discovered that frequency band or frequency range compression could be implemented with surprisingly low distortion using a minimum of components. According to this technique, a compression signal affects a component of a equalization filter. FIG. 4 shows a circuit that gave unusually good results and therefore is summarized as an embodiment.

Audio signal 400 in this embodiment is sampled and bass emphasized in opamp stage 410. The emphasized signal is amplified further by opamp stage 420 to create control signal 425. The opamps used were both portions of NE5532. Amplified control signal 425 was impressed onto light emitting diode portion 435 of optic transducer 430 (Part SE320 from Silonex) and cadmium sulfide light sensitive resistor portion 440 was used directly as a parallel shunt of equalizer circuit 450.

Circuit 450 is a treble/bass control, wherein resistances are decreased and capacitances increased proportionately to lower the impedance to a suitable value for transistor circuits (the original circuit was for vacuum tube amplifiers). During operation in one embodiment, a variable resistor in the passive equalizer was adjusted for bass, variable resistor (for example 465) was adjusted for treble, and parallel resistor shunt 440 automatically adjusts the bass response with power level. This is of course one embodiment and an electronics engineer with at least 2 years of full time work experience in audio circuit design can come up with a myriad of ways of implementing bass compression to the audio power that ultimately passes through the full range speaker

In particularly desirable embodiments, a compression element such as a resistor (cadmium sulfide cell controlled by compression signal as shown in FIG. 4) or a capacitor (a diode capacitance controlled by a voltage controlled compression signal) or an amplified capacitor is used for compression. In a desirable embodiment the compression element is directly (example parallel circuit) or indirectly connected in the same circuit as a manual control to allow a user to adjust bass and/or treble and or any frequency range, such that the compressor works with the result. This embodiment was studied and gave good results with the circuit of FIG. 4, wherein when a user turns down the bass control, the bass compressor output is less effective, (manual bass alteration and compressor bass alteration effects summed). In a particularly desirable embodiment, bass compression occurs via digital circuitry. Some or all of the circuits and methods described herein can be done via digital techniques. Software algorithms for bass compression, for example, are well known.

Having two qualitatively different signals in this way allows selective compression and enhanced stereo experience from stereo output instruments and gear, such as those made by Motsenbocker Fine Instruments of Fredericksburg, Va.

### Put Speakers/Speaker Sets in the Same Enclosure

For economy and efficiency of operation, two or more speakers as described herein may be combined in a common enclosure. In an experiment, a combination of an 8 inch subwoofer (driven by a 70 watt amplifier below 180 hertz) with a 6×9 coaxial speaker (driven by a 25 watt amplifier with bass compression with gradual rolloff below 250 hertz) provided unexpectedly superior sound. The 6×9 comprised a 6×9 woofer cone, with midrange and tweeter cones suspended in front and out of contact with the enclosure volume.

It was expected that forcing both woofer cones to share the same air space would cause problems to the 6×9 speaker due to pressure waves from the subwoofer interfering with the woofer cone movement of the 6×9 speaker. Instead, surprisingly greater clarity was found.

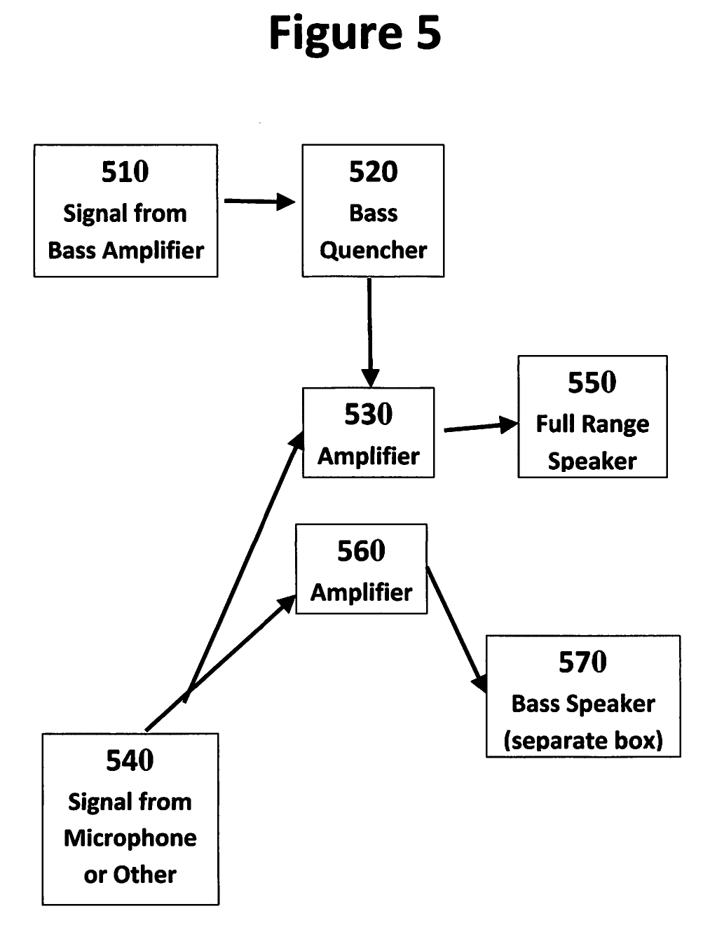

Without wishing to be bound by any one theory for this embodiment of the invention, it is hypothesized that at low bass volumes, the 6×9 full range speaker generates bass without compression and that this bass energy sums with bass from the subwoofer for improved perceived sound. At higher bass volumes, the 6×9 full range speaker bass energy tapers off and, as the subwoofer becomes more energetic with higher volume, the 6×9 progressively acts more as a passive radiator for the subwoofer. As such, the 6×9 converts the shared cabinet volume into a pseudo ported vent space. For this embodiment, a coaxial speaker having a midrange and tweeter separated from the enclosure cavity is particularly preferred, since cabinet air space pressure changes from the subwoofer will not seriously affect generation of midrange and high sounds. FIG. 5 is a diagram of this embodiment.

A “bass speaker” as termed herein is used generally to reproduce low frequencies, and includes what are termed, for example, “woofer” “woofer-midrange” and “subwoofer” drivers.

A “full range speaker” often comprises several speaker drivers that are used together to generate a full spectrum sound. For example, a tweeter can be combined with a midrange speaker, a tweeter can be combined with a midrange speaker and a woofer, a midrange speaker can be combined with a woofer, or a midrange speaker can be used by itself. Preferably, at least two, and more preferably at least three speaker elements (tweeter, midrange and woofer) are used together. The speaker elements may be driven by individual amplifiers. More preferably, the speaker elements are driven by a common amplifier and are connected through a passive crossover as is custom in this field. In a most preferred embodiment, a “coaxial speaker” is used that has two or more speaker elements mounted together. Oftentimes, such “coaxial speaker” will have a woofer cone in back and one, two or three midrange/tweeter elements in front but not necessarily all arranged concentrically. Most preferred are coaxial speakers designed for the automobile market, as these often have 3 or 4 elements and are designed for high fidelity and high efficiency.

Marching Band Speaker

An embodiment provides a battery operated backpack for marching band use by allowing co-use of a large bass (preferably subwoofer) speaker with another speaker or speaker system as described above. It was discovered that a fiberglass walled container (desired for light weight), despite some flexibility, surprisingly could work well for the mid to high range because the damping of the fiberglass wall (flexibility at differing sound pressure frequencies) was much less at the higher frequencies, such as over 100 hertz, and especially over 200 hertz.

Surprisingly, epoxy fiberglass was not as good as polyester fiberglass for the higher frequencies. Accordingly, a preferred system has a bass (preferably sub-bass) speaker driver that is ported, vented or left open, in combination with a sealed full range speaker within a polyester or other non-epoxy fiberglass enclosure, for light weight use in marching bands. It was found surprisingly that even using epoxy fiberglass with a wall thickness of less than ⅜ inch, and preferably about (+/−25%) a quarter inch thick gave good acoustic results.

If the bass amplifier to the bass speaker is low (less than 50 watts RMS and particularly less than 25 watts RMS at less than 0.1 percent interharmonic distortion, measured at 100 hertz), then the bass speaker preferably is combined in the same acoustic volume with the full range speaker. In a particularly desirable embodiment, a 6×9 full range speaker is positioned on the left side of a back pack, a 6×9 full range speaker is positioned on the right side of the back pack, and a 10 or 12 inch subwoofer is positioned in the center, facing backwards. Each of these may be driven by its own amplifier and the subwoofer may share the same acoustic volume.

It was discovered that some 20 watt RMS full range car speakers worked well when sharing the same volume with a 50 watt or less subwoofer but that sharing the same acoustic volume with a high wattage (more than 100 watt RMS to 12 inch subwoofer of medium 88 db sensitivity) subwoofer led to destruction of the full range speaker. The smaller, weaker speaker cone was being pushed the wrong way by the pressure exerted from the subwoofer cone acting in the same acoustic volume. Accordingly, in an embodiment the bass frequency power transferred to a full range speaker may be increased up to a level that prevents the cone from being pushed the opposite direction by the pressure wave from the subwoofer.

Alternative compression techniques:

Other techniques can be used to inhibit bass frequency energy input to the full range speaker. Any technique that can keep low frequency energy from passing through a speaker element used in the full range speaker has value for embodiments and preferably is controlled by a bass frequency compressor circuit. For example, in an embodiment, a MOSFET switch is used to shunt a significant (at least 50%, preferably at least 90% measured as RMS power) amount of low frequency power around a speaker that otherwise would be damaged by the low frequency power.

Multi-Use Adapter:

A particularly desirable embodiment provides a full range speaker to add mid and high range audio output to an existing bass amplifier. Furthermore, this apparatus also can be used as a regular amplifier (microphone, acoustic guitar etc). FIG. 5 is a representative outline of this apparatus. Signal 510 from a bass amp (or from bass instrument) may be a low impedance high voltage speaker output or high impedance low voltage signal output. This signal drives bass compressor circuit 520, which progressively limits (or in an embodiment, cuts off non-progressively) the low frequency bass output of amplifier 530. Another optional input, signal 540, can enter amp 530 but without bass compression. Preferably amp 530 has an equalization circuit that responds to the output of 520 and allows compression of bass as described above. Optional input of signal 540 does not activate this compression.

In an embodiment both 510 and 540 signals are handled at the same time. Preferably signal 540 (which may come from a microphone or other non-bass source) is amplified by a separate amplifier step prior to connection to amp 530. Amp 530 outputs to full range speaker 550, which reproduces a wide range from bass to treble. Speaker 550 preferably has at least 3 drivers, which preferably are mounted together in a single speaker frame as is common for car speakers.

In an embodiment, the apparatus of FIG. 5 (comprising 520, 530, 550) is housed in a single box of less than 2 cubic feet volume, preferably less than 1.5 cubic feet volume and more preferably less than 1.1 cubic feet volume. This single box apparatus preferably has a bass amplifier input, which activates a bass compressor or limiter as shown, as well as a regular input (e.g. 540), which may accept, for example, an MP3 player output or microphone output or the like. Such apparatus allows both use for improving a bass amplifier as well as acting as an MP3 player or microphone amplifier for stand alone use.

In a particularly desirable embodiment, the apparatus further includes a second amplifier (optional 560 in FIG. 5) that amplifies a full range signal (or bass range signal) and outputs a low impedance speaker driving signal suitable for a passive bass speaker (optional 570 in this figure). In this way, the apparatus can be used to improve sound quality of a big, expensive bass speaker (e.g. for bass guitar) as well as produce its own full range output for regular microphone or other (MP3) music, and further can have the capability to drive a small bass speaker. Preferably the box is small and second amplifier 560 has an output of less than 100 watts, and especially less than 50 watts RMS at less than 0.1 percent interharmonic distortion, measured at 1000 hertz.

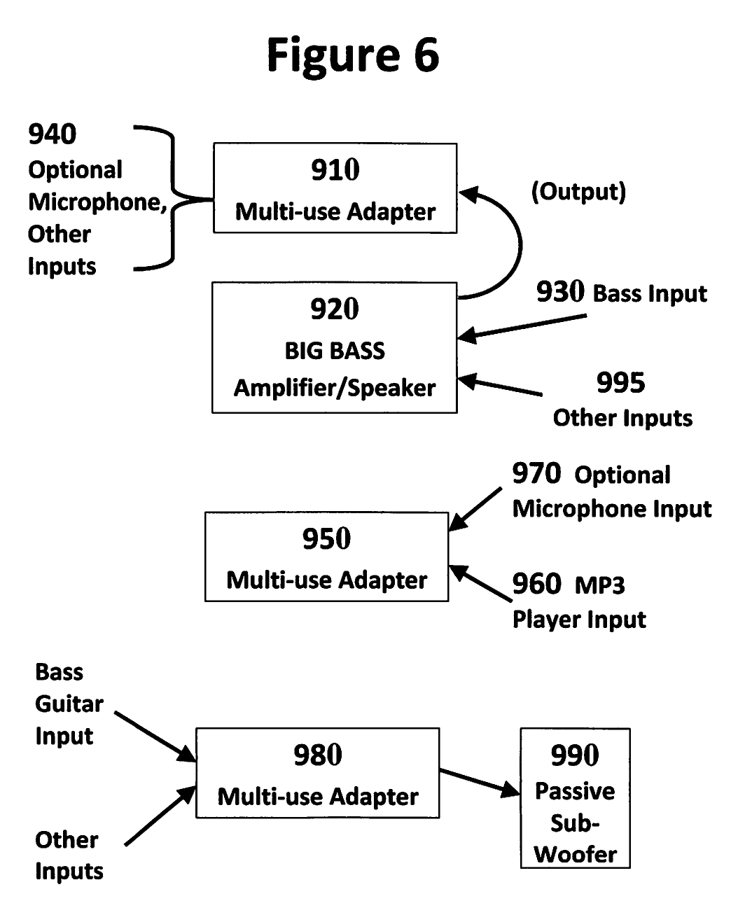

Representative uses of the multi-use adapter are shown in FIG. 6. In a first use, adapter 910 receives input (either slaved speaker driver high output or high impedance signal) from bass amplifier 920 (typically from 930 bass instrument). The multi-use adapter, via its internal full range speaker, provides midrange and high frequencies that the bass amplifier-speaker 920 lacks. This allows the input of other devices 940 to 910 (for output on the 910 speaker(s) and/or input of other devices 995 into the bass amplifier 920, for output on both devices.

In a second use, the multi-use adapter 950 is stand alone and plays MP3 or other inputs and has bass, and other outputs such as mid and treble outputs. Bass output is sufficient because the bass quencher is not needed for such audio and the bass response of adapter 950 is virtually fully used, instead of being quenched as in the case for adapter 910 above.

In a third use, multi-use adapter 980 accepts bass guitar input and, (via a second amplifier in the multi-use adapter which is not shown or used in the above two uses) outputs audio to a passive woofer driver 990, as well as outputting mostly mid and treble to the internal speaker of the 980 adapter.

In this way, the adapter can be used to a) enhance the performance of a big bass amplifier speaker system (typically 50 watts RMS output or more); b) used as a high quality MP3 speaker amplifier; and c) by adding a simple passive woofer or (preferably) subwoofer of low power (preferably less than 100 watts RMS, more preferably 50 watts or less) provide very high quality wide range sound that can reproduce bass guitar well as a stand alone unit.

Passive, (External Powered) Control System:

In an embodiment, the protection speaker system capability is added to a speaker or amplifier or active speaker system by interposing a “passive circuit” between an amplifier and a speaker.

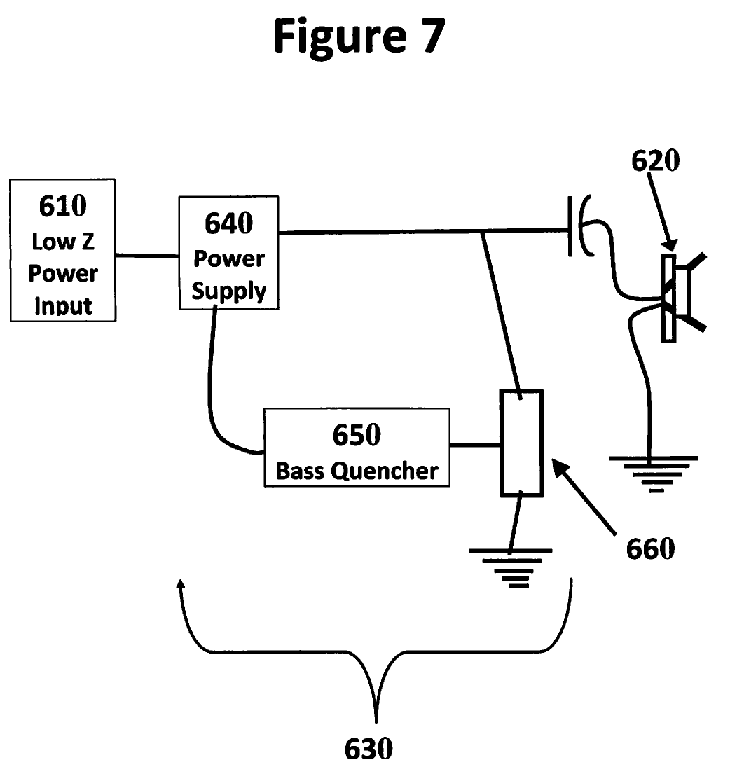

As shown in FIG. 7, a low impedance speaker drive signal 610 from an amplifier to a speaker or speaker system 620 is intercepted by interposed circuit 630. Circuit 630 is powered by the amplifier output. For example, capacitance in power capture subcircuit 640 may be charged by output from 610. A charged capacitor voltage in 640 preferably is regulated by a zener diode or other mechanism and used to power bass quencher subcircuit 650.

Preferably bass quencher subcircuit 660 progressively shunts bass power from the speaker output, thus removing the power from entering a downstream speaker, but could work as a simple limiter as well. This embodiment can be used as a black box for an existing amplifier-speaker system to improve resistance to overpowered bass audio signals that tend to arise from bass guitars. This embodiment can allow use of a regular (non bass guitar amplifier plus speaker system) to handle a bass guitar or string bass.

This passive system can be interposed between the amplifier and speaker portions of a regular amplifier-speaker system, such as an acoustic guitar or guitar or keyboard amplifier-speaker. A box or other enclosure may contain the circuit with optional inputs and outputs. Preferably, the inputs are positioned and sized to plug right into an amplifier's output terminals, such that the enclosure (preferably less than 2 cubic inches volume) is treated as a plug or plug adapter between two pieces of equipment (amplifier and speaker). The apparatus protects the speaker from noxious excessive bass signals when used with a bass instrument. Optionally, the amount of bass quenching within the apparatus, which protects the attached speaker is adjustable upon sale and/or by the user after sale to match removal of deep bass (e.g. more than 90% removal of bass signal power at frequencies less than 50 hertz) to the speaker characteristics.

Preferably, at least part of the compressed bass power is stored and used to power the circuit. In a related embodiment, the circuit does not appreciably (noticeably to the ear, e.g. not more than 1 decibel power) remove power between the amplifier and speaker unless a very strong bass signal is present, which both activates the system and provides much or most of the power to the circuit.

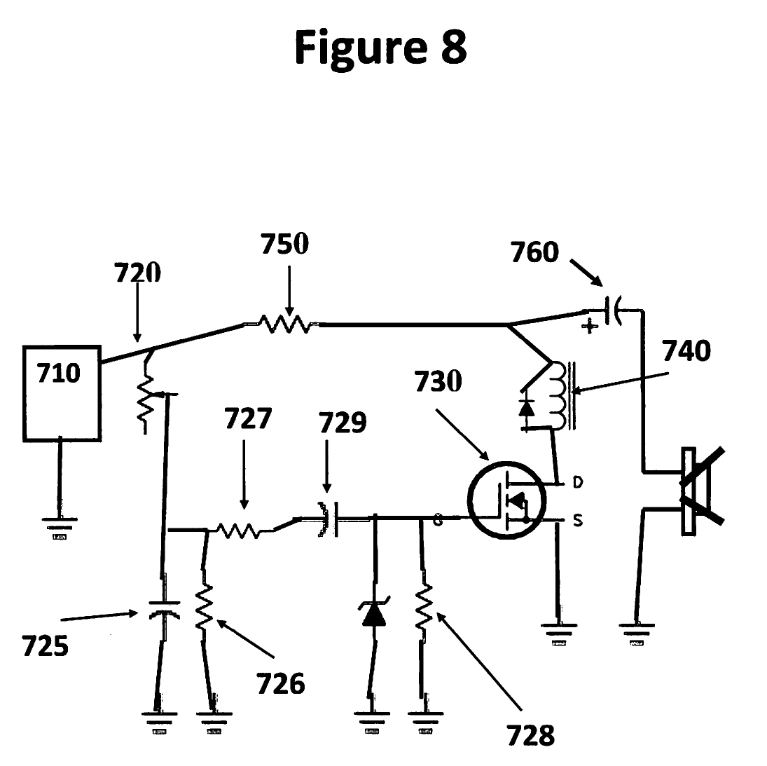

An extremely wide variety of circuits may be used to implement the passive apparatus of FIG. 7 and power supply 640 is not even needed in some embodiments. Furthermore, bass power can be removed a number of ways. Bass power may be shorted to ground as shown here, or can be subjected to a change to a series connected high impedance as described above. In an embodiment the shunt includes at least in part, a piezo speaker for audio confirmation of operation, and or a light for visual confirmation of operation. FIG. 8 shows more details for a simple representative embodiment that uses low impedance amplifier output power 710 to energize a MOSFET controller that shunts low frequency energy away from a full range speaker during high levels of low frequency audio power.

FIG. 8 shows a passive, one polarity system. Here, output 710 from a high power bass amplifier typically is low enough impedance to feed a load of between 2 to 32 ohms and more typically between 8 and 16 ohms. The audio signal is sampled by sensitivity adjust resistor 720. Capacitor 725 and resistor 726 act as a low pass filter and resistor 727 with capacitor 729 presents the sampled low frequency signal to the MOSFET 730 gate. Resistor 728 provides the very high impedance gate of MOSFET 730 a way to discharge accumulated charge. MOSFET 730 in response to a suitable signal on its gate will conduct low frequency power signal through iron core inductor 740.

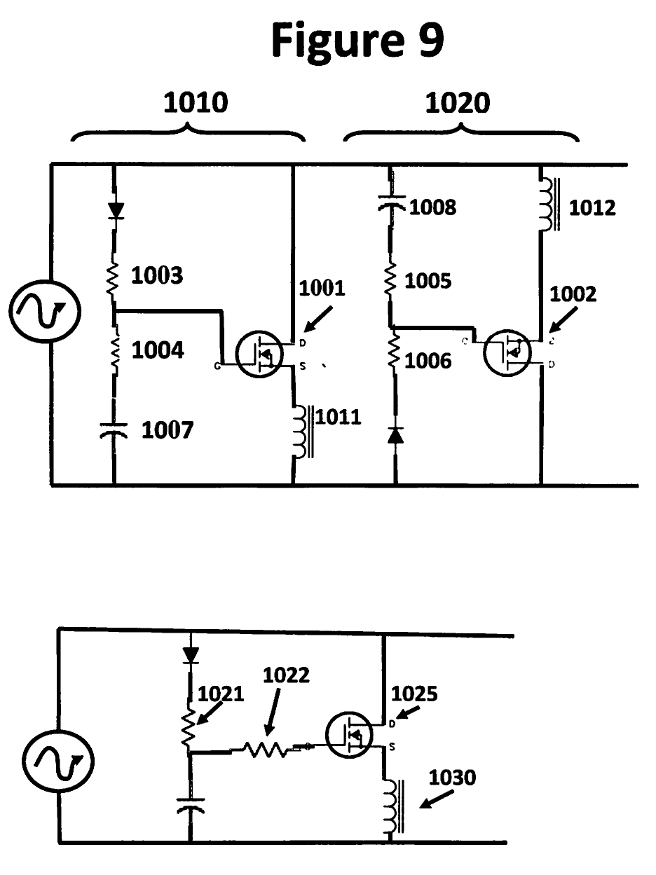

Optional high power dissipation low ohm resistor 750 helps separate the effects of low frequency shunt from the sampling signal and should be 10 ohms or less. Capacitor 760 works with inductor 740 as a passive high frequency filter for audio signal to speaker 770. The diodes shown are for protection against pulses (MOSFET gate zener) or reversed induced voltage (inductor diode). The example shown in FIG. 8 is suitable for a single polarity (pulsed DC) speaker driver and would be doubled with back to back MOSFET control for a normal AC speaker, as shown in FIG. 9.

The top circuit of FIG. 9 shows a dual polarity back to back MOSFET control of a power amplifier output on the left side that is sent to a speaker system on the right side. MOSFET 1001 (and 1002) have gates that are threshold controlled by voltage divider resistors 1003 and 1004 (and 1005 and 1006). Resistor 1004 with capacitor 1007 (and 1006, 1008) set frequency cutoff for the control signal. This shows a first order filter but a second order or third order passive filter, or even active filter, may be preferred. Low pass shunts 1011 and 1012 attenuate power to the speaker during overload and are shown as low pass here, but all pass such as resistance or conductance only, may be preferred, or some combination. A wide variety of control and filtering are contemplated.

The bottom circuit of FIG. 9 is another representative design that shows a low pass feed to the gate of MOSFET 1025 wherein trigger control may be obtained by the ratio of 1021 to 1022. MOSFET 1025 shunts power to ground via 1030.

A skilled artisan can generate a wide variety of circuits to carry out the general schemes. AGC circuit methodology is most relevant in this regard. The MOSFET design(s) summarized herein as unipolar can be implemented as bipolar (two directional) MOSFET controls. Combinations of elements presented are contemplated as will be appreciated by a skilled artisan.

A skilled artisan can appreciate many variations and further details upon reading this description and all such modifications are deemed within the scope of the claims, as space limitations preclude adding further information that already is known to such skilled artisans.

I claim:

1. An apparatus for accurately reproducing an input signal that has a large bass component, comprising:
a first audio amplifier that lacks bass compression;
a woofer connected to the first audio amplifier;
a first circuit that preferentially causes bass frequencies from the input signal to enter the woofer;
a second audio amplifier configured to reproduce a full range of frequencies;
a full range speaker for reproducing a full range of audio sound connected to the second audio amplifier;
and
a second circuit that progressively hinders bass frequencies from the input signal from entering the full range speaker at high bass signal energy levels.

2. The apparatus system of claim 1, wherein the second circuit comprises an electronic bass compressor that controls audio signal supplied to the second circuit having an attack time of no more than 10 milliseconds and a decay time of more than 20 milliseconds.

3. The apparatus of claim 1, wherein the full range speaker is a coaxial speaker that comprises tweeter, midrange and woofer drivers.

4. The apparatus of claim 1, wherein the woofer and the full range speaker are positioned in the same cabinet and share the same air space.

5. A base amplifier enhancer for improving midrange and high range audio performance of a bass amplifier comprising:
a full range audio amplifier configured to receive an audio input from the base amplifier and for driving a full range speaker;
a bass compressor operably coupled to the audio amplifier and configured to sample the audio input, preferentially increase the bass portion of the sampled signal to form a drive signal, and to use the drive signal to progressively quench the bass portion of the audio signal that is amplified and sent to the full range speaker.

6. The base amplifier enhancer of claim 5, wherein the drive signal controls an electrical component of an equalization circuit.

7. The base amplifier enhancer of claim 6, wherein the electrical component is a light sensitive resistor that is activated by a light emitting diode.

8. The base amplifier enhancer of claim 7, wherein the electrical component is connected in parallel with a user operated element.

9. The apparatus of claim 1, further comprising a compressor circuit for controlling compression of at least a treble or bass component of an electric audio signal comprising:
an equalizer that comprises one or more passive elements for controlling at least bass and treble portions of the audio signal;
a compression circuit that accepts a form of the audio signal and creates a compression signal that increases with increasing audio signal level; and
a transducer that receives the compression signal and modifies the value of a compression passive element, thereby adjusting the equalizer, in response to increases in the level of the form of the audio signal.

10. The apparatus of claim 9, wherein the transducer is a light, the compression passive element is a light sensitive resistor and the transducer is positioned to affect the compression passive element.

11. The apparatus of claim 10, wherein the compression passive element is connected in parallel with a user operated element.

12. A passive apparatus for protecting a speaker from spurious noise from an amplifier, comprising a low pass filter portion, a MOSFET connected to the low pass filter portion and a shunt connected to and controlled by the MOSFET, wherein the low pass filter portion samples output from a connected audio amplifier and presents a control signal to a MOSFET, and the MOSFET activates the shunt to attenuate power to a connected speaker in response to the control signal.

13. The apparatus of claim 12, wherein the low pass filter portion comprises an RC circuit.

14. The apparatus of claim 13, comprising two MOSFETs, each connected oppositely to the ground and signal line.

15. The apparatus of claim 12, comprising an enclosure with a first set of two electrical contacts on one side of the enclosure that are adapted to connect to the speaker terminals of an amplifier output.

16. The apparatus of claim 15, further comprising a second set of electrical contacts on another side of the enclosure that are adapted to connect to a speaker.

17. The apparatus of claim 12, further comprising a light connected as a shunt load from the source or drain of the MOSFET, for a visual indication of a transient overload.

18. A kit for adding spurious noise rejection to a speaker system, comprising the apparatus of claim 16, and instructions for how to connect the first and second set of electrical contacts to an amplifier and a speaker, respectively.
